(19) United States
(12) Patent Application Publication
(10) Pub. No.: US 2003/0132055 A1
(43) Pub. Date: Jul. 17, 2003

(54) Device using membranous valve to produce sound

(75) Inventors: Steven Gautieri, Gladstone, MO (US); Mrako Fenster, Basehor, KS (US); Larry Guerra, Shawnee, KS (US); Jonathon K. Kemnitzer, Kansas City, MO (US)

Correspondence Address: HOVEY WILLIAMS TIMMONS & COLLINS, 2405 GRAND BLVD., SUITE 400, KANSAS CITY, MO, 64108

(73) Assignee: WORLD 2 TOYS, INC.

(21) Appl. No.: 10/051,552

(22) Filed: Jan. 17, 2002

(51) Int. Cl. H05K 5/00

(52) U.S. Cl. 181/148

(57) ABSTRACT

A device (10) for producing sound, such as, for example, simulated animal calls for hunting or flatulence or other bodily noises for entertainment, using a membranous valve (17) including one or more vibrating thermoplastic or thermoset plastic membranes (18,20), wherein said vibration is mechanically induced by a gas, such as air, releasing from a reservoir (12). In a preferred embodiment, the device (10) is hand-held, portable, and broadly comprises the reservoir (12); a return (14); a focuser (16); the membranous valve (17); and an emitter (22). Gas released from the reservoir (12) is directed by the focuser (16) to pass across the one or more membranes (18,20) which are held in their operating positions by the emitter (22). Vibration of an edge portion of each membrane (18,20) produces the desired sound.

### BACKGROUND OF THE INVENTION

1. Field of the Invention

The present invention relates broadly to devices for producing sound using vibrating membranes. More particularly, the present invention relates to a portable device for producing sound, such as, for example, simulated animal calls or flatulence or other bodily noises, using a membranous valve including one or more vibrating thermoplastic orthermoset plastic membranes, wherein said vibration is mechanically induced by a gas, such as air, releasing from a reservoir.

2. Description of the Prior Art

It is often desirable to artificially produce a realistic sound, such as, for example, simulated animal calls for hunting or flatulence or other bodily noises for entertainment. Numerous devices exist for this purpose, being either electrical or mechanical in nature and varying greatly in complexity and cost. Unfortunately, these existing devices typically produce a cold, unlifelike, and unrealistic sound. Furthermore, such sound is typically identical and without realistic variation with each activation. Due to this lack of realism, these existing devices are unlikely to satisfactorily serve their desired purpose.

One existing battery-powered electronic device, for example, is operable to replay a limited number of pre-recorded sounds using a small speaker or other electroacoustic mechanism. It will be appreciated, however, that, where the device is intended for use under relatively extreme operating conditions, such as, for example, in rough-and-tumble outdoor or social settings, it is desirable that the device be inexpensively and simply constructed so as to either avoid damage or be economically replaceable if damaged.

One well-known inexpensive and simply constructed mechanical device, for example, operable to reproduce simulated flatulence noises comprises a hand-held substantially cylindrical collapsible reservoir having a single outlet hole. In operation, a user places the expanded reservoir in their hand in such a manner that the outlet hole is adjacent a palm portion of the hand. A squeezing force causes the reservoir to collapse, thereby forcibly expelling a volume of air through the outlet hole. This expulsion of air causes the skin of the palm to vibrate, thereby producing the desired simulated flatulence noise. The acoustic characteristics of the noise may be altered by changing the positioning of the outlet hole against the palm or the squeezing force with which the reservoir is collapsed.

This existing device, however, because it relies on induced vibration of human skin, requires some practice and skill with regard to placement of the outlet hole in order to reliably produce sound when desired. Furthermore, the vibratory qualities of human skin may frequently change depending on a number of environmental and biological factors, including, for example, the moisture content and corresponding pliability of the skin. Additionally, even when functioning reliably, the skin of the palm may be unsuitable for simulating certain sounds with sufficient accuracy.

Due to these and other limitations and problems in the art, a need exists for a simple and inexpensive device operable to reliably produce sounds of satisfactory simulative quality.

### SUMMARY OF THE INVENTION

The present invention is a distinct advance in the art of devices for producing sound using vibrating membranes. More particularly, the present invention provides a device for reliably and realistically producing a variety of sounds, such as, for example, simulated animal calls or flatulence or other bodily noises, using a membranous valve including one or more vibrating thermoplastic or thermoset plastic membranes, wherein said vibration is mechanically induced by release of a gas, such as air.

In a preferred embodiment, the device is hand-held, portable, and broadly comprises a reservoir; a return; a focuser; the membranous valve including the one or more membranes; and an emitter. The reservoir is operable to contain and forcibly expel, release, or otherwise move a volume of gas, such as, for example, air or carbon dioxide (CO₂). The reservoir may take the form of a collapsible bulb or cap, having an open bottom or other opening operable to allow the gas to directedly escape the collapsing reservoir. An exterior surface of the reservoir may present knurls or knobs to facilitate a user's grip.

The return is operable to allow the gas to reenter the collapsed reservoir as the reservoir naturally re-expands. The return may take the form of a simple closeable hole in the reservoir, or a conventional one-way check valve operable to allow the gas to pass into the reservoir but not thereoutof.

The focuser is operable to both controlledly direct or focus the gas being expelled from the reservoir and, in some embodiments, provide a mechanism for coupling the reservoir with the emitter. The focuser is secured over the open bottom or other opening of the reservoir using, for example, threaded screws or an engaging snap-on lip, possibly supplemented with a silicon-based or similar sealing material. The focuser presents a focus hole operable to direct the flow of expelled gas over the membranes.

The membranous valve includes the one or more membranes operable to vibrate in response to the gas being expelled through the focus hole of the focuser. The membranes are constructed of either a thermoplastic polymer gel or a thermoset plastic.

The emitter is operable to maintain the membranes in their proper operating positions adjacent the focus hole while still allowing the membranes to vibrate. The emitter may be constructed of hard plastic or pliable fabric, and may include one or more sound holes wherethrough sound produced by the device is emitted. The emitter may couple with the reservoir either directly or via the focuser.

In use and operation, the fully-expanded reservoir is squeezed to force air through the hole provided in the focuser. The air then flows across the first membrane to an edge thereof which is adjacent the sound hole of the emitter. The air causes the edges of the one or more membranes to vibrate such that sound is produced and emitted through the sound hole. As squeezing subsides, the reservoir naturally re-expands by drawing air through the return.

It will be appreciated that the acoustic characteristics of the sound produced by the device depend on and may be varied with the shape and nature of the reservoir; the shape of the focuser; the shape, pliability, and other physical characteristics of the membranes; the shape of the emitter; and the force and positioning of the user's hand. By way of illustration, various alternative embodiments and implementations are also discussed herein.

These and other important aspects of the present invention are more fully described in the section entitled DETAILED DESCRIPTION, below.

### BRIEF DESCRIPTION OF THE DRAWINGS

A preferred embodiment of the present invention is described in detail below with reference to the attached drawing figures, wherein:

FIG. 1 is an exploded isometric view of a preferred first embodiment of the present invention;

FIG. 2 is an assembled right side sectional elevation view of the embodiment shown in FIG. 1;

FIG. 3 is an exploded isometric view of a preferred second embodiment of the present invention;

FIG. 4 is an assembled right side sectional elevation view of the embodiment shown in FIG. 3; and

FIG. 5 is a left side elevation view of a preferred third embodiment of the present invention.

### DETAILED DESCRIPTION OF THE PREFERRED EMBODIMENT

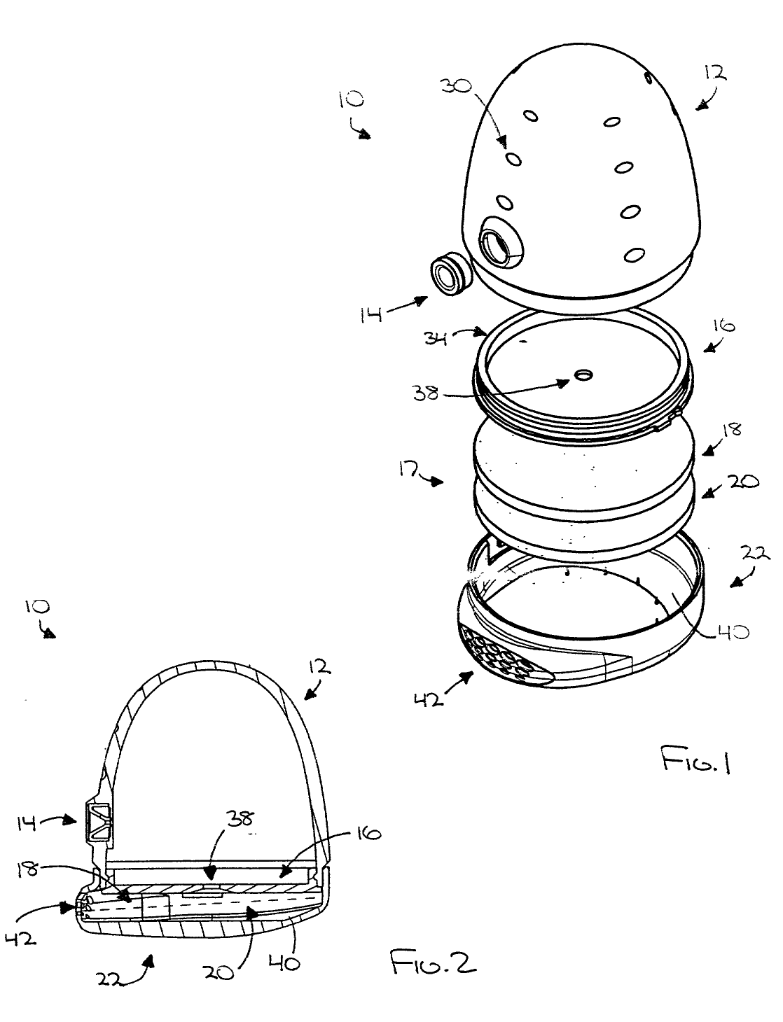

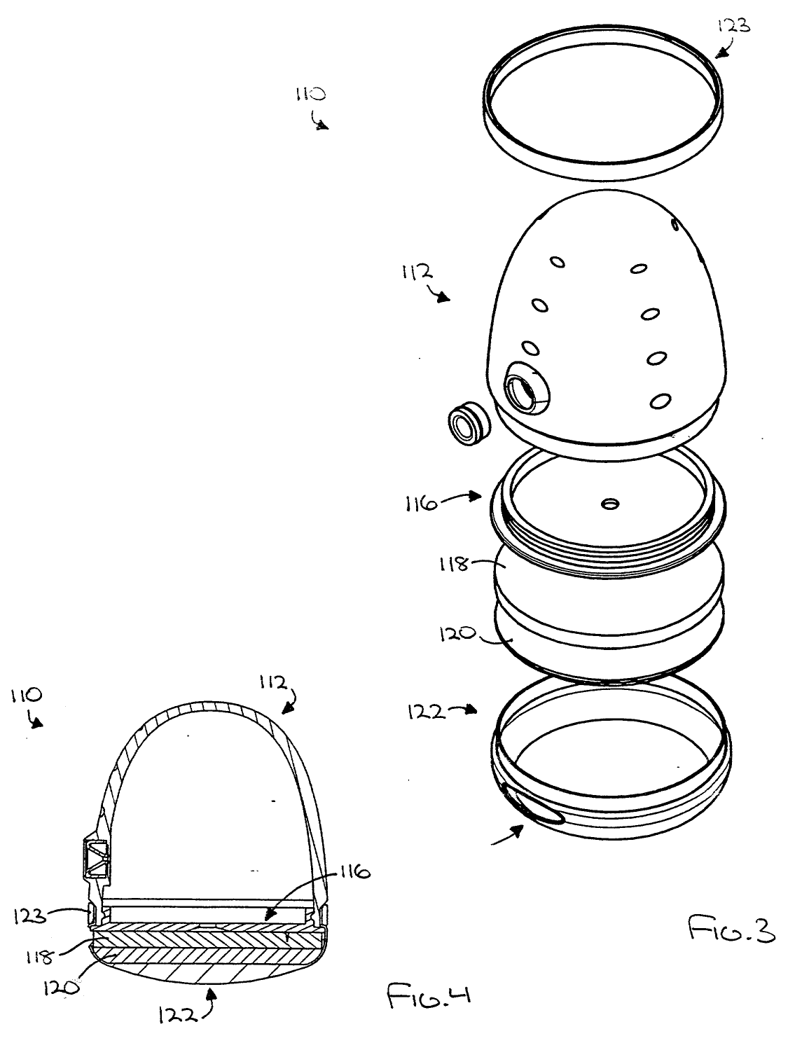

Referring to FIGS. 1 and 2, a device 10 is shown constructed in accordance with a preferred first embodiment of the present invention. The device 10 is operable to produce sound, such as, for example, animal calls for hunting or flatulence or other bodily noises for entertainment, using a membranous valve 17 including one or more vibrating thermoplastic or thermoset plastic membranes 18,20, wherein said vibration is mechanically induced by air movement across the membranes 18,20. The device 10 broadly comprises a reservoir 12; a return 14; a focuser 16; the membranous valve 17 including a first membrane 18 and a second membrane 20; and an emitter 22.

The reservoir 12 is operable to contain and forcibly expel, release, or otherwise move a volume of gas, such as, for example, air or carbon dioxide (CO₂). As illustrated, the reservoir 12 is a substantially half-spherical collapsible bulb or cap, with an approximate maximum volume of between fifteen and fifty cubic centimeters, and operable to withstand and provide maximum gas pressures of approximately 15 PSI. An exterior surface of the reservoir 12 may present knurls or knobs 30 to facilitate a user's grip. The reservoir 12 has an open bottom which operates as a gas outlet to allow the gas to directedly escape the collapsing reservoir 12. It will be appreciated that the present invention is substantially independent of any particular shape, size, or nature of reservoir, being more concerned with the reservoir's ability to contain and forcibly expel a sufficient volume of gas given the type and volume of the desired sound. Thus, the reservoir 12 may be alternatively embodied in, for example, a conventional bellows, a commonly available CO₂ cartridge, or a user's mouth.

The return 14 is operable to allow the gas to reenter the collapsed reservoir 12 as the reservoir 12 re-expands. The return 14 may be a simple coverable or otherwise closeable hole in the reservoir 12, or may be a conventional one-way check valve operable to allow the gas to pass into the reservoir 12 but not thereoutof. Alternatively, the return 14 may be embodied in any suitable valve mechanism, such as, for example, an in-line valve, a diaphragm-based valve, or a conventional flap valve. It will be appreciated, however, that the return 14 is not applicable to all reservoir types, being instead limited in application to collapsible/expandable reservoir types. Thus, the return 14 might not be included or needed where the reservoir 12 is, for example, a factory-pressuized CO₂ cartridge.

The focuser 16 is operable to both controlledly direct or focus the gas being expelled from the reservoir 12 and, in some embodiments, provide a mechanism for coupling the reservoir 12 with the emitter 20. As illustrated, the focuser 16 is substantially circular, constructed of hard plastic or other similar material, and secured over the open bottom of the reservoir 12 using, for example, threaded screws or an engaging snap-on lip 34, possibly supplemented with a silicon or similar sealing material. The focuser 16 includes a substantially circular center hole 38 operable to direct the flow of expelled gas over the membranes 18,20. It will be appreciated that the location, size, shape, and other characteristics of the hole 38 may vary depending on the volume and nature of the desired sound. Furthermore, the shape of the focuser 16 and its securement to the reservoir 12 will vary depending on the shape and nature of the reservoir 12.

The membranous valve 17 includes the first and second membranes 18,20 operable to vibrate in response to the gas being expelled through the center hole 38 of the focuser 14. As illustrated, the first and second membranes 18,20 are constructed of either a thermoplastic polymer gel or a thermoset plastic such as rubber or a synthetic equivalent thereof. Alternatively, the membranes 18,20 may be constructed of any suitable natural or synthetic material, such as, for example, rubber or latex. A lubricant or other wetting compound may be added to the membranes 18,20 to result in an even more realistic sound.

The emitter 20 is operable to maintain the first and second membranes 18,20 in their proper operating positions adjacent the hole 38 while still allowing the membranes 18,20 to vibrate. As illustrated, the emitter 20 is constructed of plastic or of similarly relatively hard material, and includes a sound hole 42 wherethrough sound produced by the device 10 is emitted. The emitter 20 includes a sloped portion 40 operable to provide pressure on an edge of each membrane 18,20 which is opposite the sound hole 42. The effect of this pressure is to cause the air to flow across the membrane 18 in the direction of the sound hole 42 where the resulting sound is better heard. The emitter 20 may couple with the reservoir 12 either directly or via the focuser 14, and is preferably adjustable thereupon with regard to said pressure. It will be appreciated that the emitter 20 and the sound hole 42 may vary in shape and construction so as to affect different acoustical effects and achieve the desired sound.

In use and operation, the reservoir 12 is initially fully expanded and contains a volume of air. The user grasps the reservoir 12 and squeezes to force the air from the collapsing reservoir 12 through the hole 38 in the focuser 16. The air is then forced across the first membrane 18 to an edge thereof which is adjacent the sound hole 42 of the emitter 22. The air causes the edges of the first and second membranes 18,20 to vibrate such that sound is produced and emitted through the sound hole 42. As the user releases pressure, the reservoir 12 naturally re-expands by drawing air through the return 14.

It will be appreciated that the acoustic characteristics of the sound produced by the device 10 depend on and may be varied with the shape and nature of the reservoir 12; the shape of the focuser 16; the shape, pliability, and other physical characteristics of the membranes 18,20; the shape of the emitter 22; and the force and positioning of the user's hand.

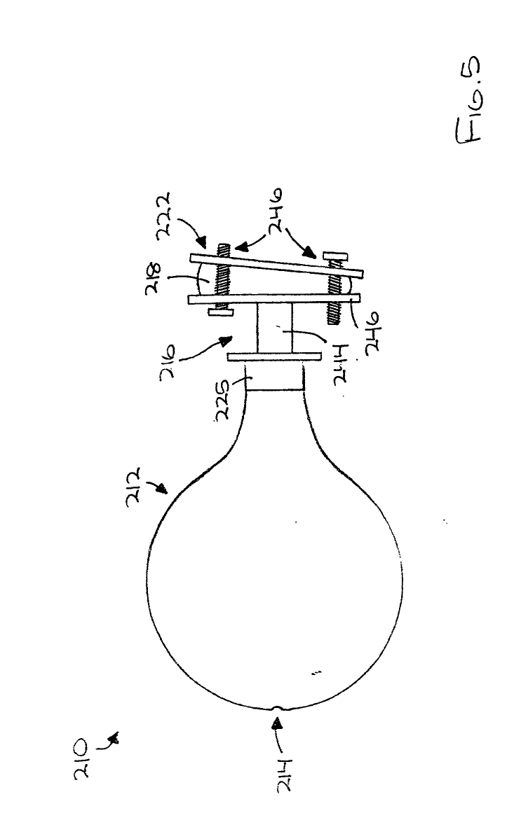

Referring to FIGS. 3 and 4, the device 110 is shown constructed in accordance with a preferred second embodiment which is substantially similar to the preferred first embodiment, described above. In the preferred second embodiment, however, the emitter 122 is constructed of a pliable material, such as, for example, fabric. The emitter 122 may be chemically affixed, using glue or a similar bonding material, to either the focuser 116 or directly to the reservoir 112. In order to further ensure securement of the emitter 122 in its operating position, a compression ring 123 may be included operable to fit over both the emitter fabric and either the focuser 116 or the reservoir 112, as appropriate. The compression ring 123 may be a stretchable ring of natural or synthetic material, such as a common rubber band, or, alternatively, a ring of heat-shrinkable material.

In operation, the device 110 of the preferred second embodiment operates substantially similar to the preferred first embodiment, described above. The greater pliability of the emitter 122, however, allows for greater control over vibration of the first and second membranes 118,120 and, thus, greater control over the acoustic characteristics of the sound produced. Because the fabric emitter 122 does not provide the sloped portion 40 of the emitter 22 described in the preferred first embodiment, the user must apply pressure to that portion of the emitter 122 which is opposite the sound hole 142 so that the air is forced toward the sound hole 142 where the resulting sound is better heard.

Referring to FIG. 5, the device 210 is shown constructed in accordance with a preferred third embodiment which is substantially similar in operation to the preferred first and second embodiments described above. In the preferred third embodiment, however, the reservoir 212 is substantially spherical and couples with the focuser 216 via a coupling collar 225. The return 214 is present in this embodiment as well. The focuser 216 includes a hollow cylindrical tube 244 and a wall 246. The tube 244 is operatively coupled with the reservoir 212 via the coupling collar 225, and extends outwardly therefrom to intersect the wall 225 at the center hole (not shown). The emitter 222 is substantially planar and adjustably couples with the wall 225 of the focuser 216 using a plurality of screws 246. Only one membrane 218 is shown, it being clamped between the wall 225 and the emitter 222. The clamping force on the membrane 218 may be lessened or increased by adjusting the screws 246 which varies the membrane's ability to vibrate and thereby affects the acoustic characteristics of the generated sound. Additionally, the screws 246 may be adjusted so that greater pressure is applied to one edge of the membrane 218, thereby causing the air to flow toward and sound 10 to be produced at the edge which is under less pressure.

In operation, the reservoir 212 is squeezed to force air contained therein through the focuser tube 244 and the center hole in the wall 246. Thereafter, the air is forced across the membrane 218 in a manner determined by the clamping force exerted on the membrane 218 by the wall 246, emitter 222, and screws 246. As in previously described embodiments, this movement of air causes the membrane 218 to vibrate and produce the desired sound.

From the preceding description, it can be appreciated that the present invention provides a simple and inexpensive device 10 operable to produce sound, such as, for example, animal calls or flatulence or other bodily noises, by directing air over the first and second membranes 18,20 in order to cause said membranes 18,20 to vibrate.

Although the invention has been described with reference to the preferred embodiment illustrated in the attached drawings, it is noted that equivalents may be employed and substitutions made herein without departing from the scope of the invention as recited in the claims. Furthermore, applications are contemplated for the tool herein described that require only minor modifications to the tool as disclosed. Thus, for example, the shape and nature of the reservoir; the shape of the focuser; the shape, pliability, and other physical characteristics of the first and second membranes; and the shape of the emitter may be varied so as to achieve the acoustical characteristics of the desired sound.

Having thus described the preferred embodiment of the invention, what is claimed as new and desired to be protected by Letters Patent includes the following:

1. A device operable to produce sound using vibration mechanically induced by movement of a gas, the device comprising:
a reservoir operable to contain a volume of the gas, the reservoir including an outlet wherethrough the gas may be released;
a membrane positioned near the outlet and operable to vibrate in response to the gas being released from the reservoir; and
an emitter operable to maintain the membrane near the outlet while still allowing the membrane to vibrate, the emitter including a sound hole wherethrough sound produced by the device is emitted.

2. The device as set forth in claim 1, wherein the reservoir is a collapsible bulb and the gas is ordinary air.

3. The device as set forth in claim 2, wherein the reservoir has a maximum volume of 15-50 cubic centimeters.

4. The device as set forth in claim 1, where the gas is carbon dioxide.

5. The device as set forth in claim 1, wherein the membrane includes a thermoplastic polymer gel material.

6. The device as set forth in claim 1, wherein the membrane includes a thermoset plastic material.

7. The device as set forth in claim 1, wherein the emitter is constructed of a substantially pliable material.

8. The device as set forth in claim 7, wherein the emitter is constructed of fabric.

9. The device as set forth in claim 1, further comprising a one-way valve penetrating the reservoir, wherein the one-way valve is operable to allow the gas to pass into the reservoir but not thereoutof.

10. The device as set forth in claim 1, further comprising a focuser interposed between the reservoir and the membrane and providing a focusing mechanism operable to direct the release of the gas from the reservoir across the membrane.

11. The device as set forth in claim 1, where in the emitter provides an adjustable pressure upon the membrane, wherein adjustment of the pressure affects acoustic characteristics of the sound.

12. The device as set forth in claim 1, where the emitter provides an uneven pressure on the membrane such that less pressure is applied near the sound hole causing the gas to naturally flow theretoward.

13. A handheld device operable to produce sound using vibration mechanically induced by movement of air, the device comprising:
a collapsible bulb operable to contain a maximum volume of air between 1550 cubic centimeters, the bulb including an outlet wherethrough the air may be forced by collapsing the bulb;
a synthetic membrane positioned near the outlet and operable to vibrate in response to air being forced from the bulb; and
an emitter operable to maintain the synthetic membrane near the outlet while still allowing the synthetic membrane to vibrate.

14. The device as set forth in claim 13, wherein the emitter is constructed of a substantially pliable material.

15. The device as set forth in claim 14, wherein the emitter is constructed of fabric.

16. The device as set forth in claim 13, further comprising a one-way valve operable to allow the gas to pass into the collapsible bulb but not thereoutof.

17. The device as set forth in claim 13, further comprising a focuser interposed between the collapsible bulb and the synthetic membrane and providing a focusing mechanism operable to direct the release of the gas from the outlet across the synthetic membrane.

18. The device as set forth in claim 13, where in the emitter provides an adjustable pressure upon the synthetic membrane, wherein adjustment of the pressure affects acoustic characteristics of the sound.

19. The device as set forth in claim 1, where the emitter provides an uneven pressure on the synthetic membrane such that less pressure is applied near the sound hole causing the gas to naturally flow theretoward.

20. A handheld device operable to produce sound using vibration mechanically induced by movement of air, the device comprising:
a collapsible bulb operable to contain a maximum volume of air between 15-50 cubic centimeters, the bulb including an outlet wherethrough the air may be forced by collapsing the bulb;
a synthetic membrane positioned near the outlet and operable to vibrate in response to the air being forced through the outlet;
an emitter operable to maintain the synthetic membrane near the outlet while still allowing the synthetic membrane to vibrate, with the emitter being further operable to provide an adjustable degree and evenness of pressure on the synthetic membrane wherein the degree of pressure affects acoustic characteristics of the sound, and the evenness of pressure affects directional flow of the gas across the synthetic membrane.

21. The device as set forth in claim 20, further comprising a one-way valve operable to allow the gas to pass into the bulb but not thereoutof.

22. The device as set forth in claim 20, further comprising a focuser interposed between the collapsible bulb and the synthetic membrane and providing a focusing mechanism operable to direct the release of the gas from the outlet across the synthetic membrane.
